(19) United States
(12) Patent Application Publication
(10) Pub. No.: US 2007/0144915 A1
(43) Pub. Date: Jun. 28, 2007

(54) PROCESS AND COMPOSITION FOR PASSIVATING A SUBSTRATE DURING ELECTROCHEMICAL MECHANICAL POLISHING

(75) Inventors: Yuan A. Tian, San Jose, CA (US); Renhe Jia, Berkeley, CA (US); Feng Q. Liu, San Jose, CA (US); Yongqi Hu, San Jose, CA (US); Stan D. Tsai, Fremont, CA (US); Liang-Yuh Chen, Foster City, CA (US); Robert A. Ewald, Aptos, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/613,918

(22) Filed: Dec. 20, 2006

Related U.S. Application Data
(60) Provisional application No. 60/753,125, filed on Dec. 22, 2005.

(51) Int. Cl. B23H 7/00; H05K 3/07

(52) U.S. Cl. 205/640

(57) ABSTRACT

Compositions and methods for processing a substrate having a conductive material layer disposed thereon are provided. In one embodiment, a method of electrochemically processing a substrate using a conductive polishing article is provided. The method includes disposing a substrate having a conductive material layer formed thereon in a process apparatus comprising a cathode coupled to the conductive polishing article and an anode, wherein the substrate is in electrical contact with the anode, supplying a polishing composition comprising a cathodic inhibitor and an anodic inhibitor, forming a protective film on the cathode to prevent corrosion of the cathode, and polishing the substrate. In another embodiment, a composition for processing a substrate having a conductive material layer disposed thereon is provided which composition includes a corrosion inhibitor selected from the group of an amino acid based inhibitor, a polymeric based corrosion inhibitor, an oxidizer, a chelating inhibitor or combinations thereof.

### CROSS-REFERENCE TO RELATED APPLICATIONS

This application claims benefit of U.S. provisional patent application Ser. No. 60/753,125 (APPM/010108L), filed Dec. 22, 2005, which is herein incorporated by reference.

### BACKGROUND OF THE INVENTION

1. Field of the Invention

Embodiments of the present invention relate to compositions and methods for removing a conductive material from a substrate.

2. Background of the Related Art

Reliably producing sub-half micron and smaller features is one of the key technologies for the next generation of very large scale integration (VLSI) and ultra large-scale integration (ULSI) of semiconductor devices. However, as the limits of circuit technology are pushed, the shrinking dimensions of interconnects in VLSI and ULSI technology have placed additional demands on processing capabilities. Reliable formation of interconnects is important to VLSI and ULSI success and to the continued effort to increase circuit density and quality of individual substrates and die.

Multilevel interconnects are formed using sequential material deposition and material removal techniques on a substrate surface to form features therein. As layers of materials are sequentially deposited and removed, the uppermost surface of the substrate may become non-planar across its surface and require planarization prior to further processing. Planarization or “polishing” is a process in which material is removed from the surface of the substrate to form a generally even, planar surface. Planarization is useful in removing excess deposited material, removing undesired surface topography, and surface defects, such as surface roughness, agglomerated materials, crystal lattice damage, scratches, and contaminated layers or materials to provide an even surface for subsequent photolithography and other semiconductor manufacturing processes. One conventional process for planarization is by chemical mechanical polishing (CMP), which planarizes a layer by chemical activity and mechanical activity.

It is extremely difficult to planarize a metal surface, particularly a copper surface, of a damascene inlay as shown in FIGS. 1A and 1B, with a high degree of surface planarity using a chemical mechanical polishing process. A damascene inlay formation process may include etching feature definitions in an interlayer dielectric, such as a silicon oxide layer, sometimes including a barrier layer in the feature definition and on a surface of the substrate, and depositing a thick layer of copper material on the substrate surface and any barrier layer if present. Chemical mechanically polishing the copper material to remove excess copper above the substrate surface often insufficiently planarizes the copper surface. Chemical mechanical polishing techniques to completely remove the copper material often results in topographical defects, such as dishing and erosion that may affect subsequent processing of the substrate.

However, materials deposited on the surface of a substrate to fill feature definitions formed therein often result in unevenly formed surfaces over feature definitions of variable density. Referring to FIG. 1A, a metal layer 20 is deposited on a substrate 10 to fill wide feature definitions 30, also known as low density feature definitions, or narrow feature definitions 40, also known as and high density feature definitions. Excess material, called overburden, may be formed with a greater thickness 45 over the narrow feature definitions 40 and may have minimal deposition 35 over wide feature definitions 30. Polishing of surfaces with overburden may result in the retention of residues 50 from inadequate metal removal over narrow features. Overpolishing processes to remove such residues 50 may result in excess metal removal over wide feature definitions 30. Excess metal removal can form topographical defects, such as concavities or depressions known as dishing 55, over wide features, as shown in FIG. 1B.

Dishing occurs when a portion of the surface of the inlaid metal of the interconnection formed in the feature definitions in the interlayer dielectric is excessively polished, resulting in one or more concave depressions, which may be referred to as concavities or recesses. Referring to FIG. 1A, a damascene inlay of lines 11 are formed by depositing copper (Cu) or a copper alloy, in a damascene opening formed in interlayer dielectric 10, for example, silicon dioxide. While not shown, a barrier layer of a suitable material such as titanium (or tantalum) and/or titanium nitride (or tantalum nitride) for copper may be deposited between the interlayer dielectric 10 and the inlaid metal 12. Subsequent to planarization, a portion of the inlaid metal 12 may be depressed by an amount D, referred to as the amount of dishing. Dishing is more likely to occur in wider or less dense features on a substrate surface.

Additionally, residual material may remain after a polishing process. In such instances a second polishing step or an overpolishing process may be performed to remove the remaining material. However, such processes may result in erosion, characterized by excessive polishing of the layer not targeted for removal, such as a dielectric layer surrounding a metal feature. Referring to FIG. 1B, a copper line 21 and dense array of copper lines 22 are inlaid in interlayer dielectric 20. The process to polish the copper lines 22 may result in loss, or erosion E, of the dielectric 20 between the metal lines 22. Erosion is observed to occur near narrower or more dense features formed in the substrate surface. Modifying conventional copper CMP polishing techniques has resulted in less than desirable polishing rates and less than desirable polishing results than commercially acceptable.

Therefore, there is a need for compositions and methods for removing conductive material, such as excess copper material, from a substrate that minimizes the formation of topographical defects to the substrate during planarization.

### SUMMARY OF THE INVENTION

In one embodiment, a method of electrochemically processing a substrate using a conductive polishing article is provided. The method includes disposing a substrate having a conductive material layer formed thereon in a process apparatus comprising a cathode coupled to the conductive polishing article and an anode, wherein the substrate is in electrical contact with the anode, supplying a polishing composition comprising a cathodic inhibitor and an anodic inhibitor, forming a protective film on the cathode to prevent corrosion of the cathode, and polishing the substrate.

In another embodiment, a method of electrochemically processing a substrate using a conductive polishing article is provided. The method includes disposing a substrate having a conductive material layer formed thereon in a process apparatus comprising a first electrode and a second electrode, wherein the substrate is in electrical contact with the second electrode, providing a polishing composition between the first electrode and the substrate, wherein the polishing composition initially comprises an acid based electrolyte, a corrosion inhibitor selected from the group of an amino acid based inhibitor, a polymeric based corrosion inhibitor, an oxidizer, a chelating inhibitor, or combinations thereof, a pH adjusting agent, a solvent, and a pH between about 1 and about 10, forming a protective film on a polishing article coupled to the second electrode, contacting the substrate to the polishing article, providing relative motion between the substrate and the polishing article, and removing conductive material from the substrate.

In yet another embodiment, a method of electrochemically processing a substrate using a conductive polishing article, comprising providing a process apparatus comprising a cathode coupled to the conductive polishing article and an anode, supplying a polishing composition comprising a cathodic inhibitor, and forming a protective film on the cathode to prevent corrosion of the cathode.

In yet another embodiment, a composition for processing a substrate having a conductive material layer disposed thereon is provided which composition includes an acid based electrolyte, a corrosion inhibitor selected from the group of an amino acid based inhibitor, a polymeric based corrosion inhibitor, an oxidizer, a chelating inhibitor or combinations thereof, a pH adjusting agent, a solvent, and a pH between about 1 and about 10.

### BRIEF DESCRIPTION OF THE DRAWINGS

So that the manner in which the above recited aspects of the present invention are attained and can be understood in detail, a more particular description of embodiments of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1B are schematic cross-sectional views illustrating a polishing process performed on a substrate according to conventional processes; and

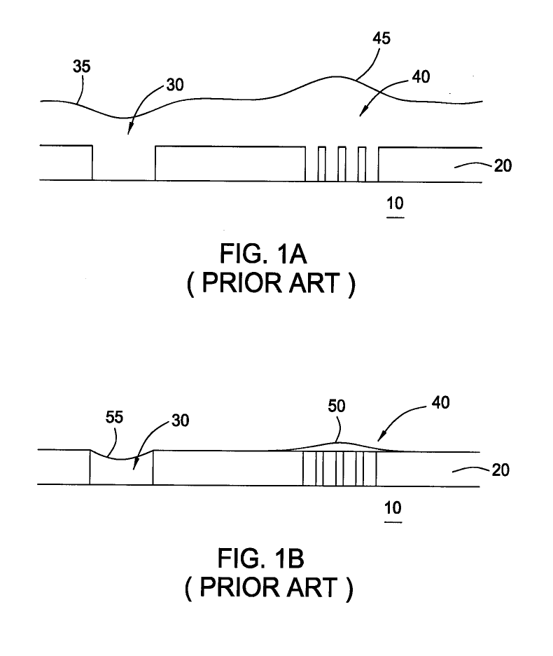

FIGS. 2A-2D are schematic cross-sectional views illustrating a polishing process performed on a substrate according to one embodiment for planarizing a substrate surface described herein.

To facilitate understanding, identical reference numerals have been used, wherever possible, to designate identical elements that are common to the figures. It is to be contemplated that elements and/or process steps of one embodiment may be beneficially incorporated in other embodiments without additional recitation.

### DETAILED DESCRIPTION OF THE PREFERRED EMBODIMENT

In general, aspects of the inventions provide compositions and methods for removing at least a conductive material from a substrate surface. The inventions are described below in reference to a planarizing process for the removal of conductive materials from a substrate surface by an electrochemical mechanical polishing (Ecmp) technique with a composition having a corrosion inhibitor.

The words and phrases used herein should be given their ordinary and customary meaning in the art by one skilled in the art unless otherwise further defined. Chemical mechanical polishing should be broadly construed and includes, but is not limited to, planarizing a substrate surface using chemical activity and mechanical activity, or a concurrent application of chemical activity and mechanical activity. Electropolishing should be broadly construed and includes, but is not limited to, removing material from a substrate by eroding the substrate surface under application of electric current. Electrochemical mechanical polishing (Ecmp) should be broadly construed and includes, but is not limited to, planarizing a substrate by the application of a combination of electrochemical, chemical, and mechanical activity to remove material from a substrate surface.

Anodic dissolution should be broadly construed and includes, but is not limited to, the application of an anodic bias to a substrate directly or indirectly which results in the removal of conductive material from a substrate surface and into a surrounding polishing composition. Polishing composition should be broadly construed and includes, but is not limited to, a composition that provides ionic conductivity, and thus, electrical conductivity, in a liquid medium, which generally comprises materials known as electrolyte components. The amount of each component in the polishing compositions can be measured in volume percent or weight percent. Volume percent refers to a percentage based on volume of a desired liquid component divided by the total volume of all of the liquid in the complete composition. A percentage based on weight percent is the weight of the desired component divided by the total weight of all of the liquid components in the complete composition. Abrading and abrasion should be broadly construed and includes, but is not limited to, contacting a material and displacing, disturbing, or removing all or a portion of the material.

The electrochemical mechanical polishing process described herein may be performed in a process apparatus, such as a platform having one or more polishing stations adapted for electrochemical mechanical polishing processes, as described in co-pending U.S. patent application Ser. No. 10/378,097, filed on Feb. 26, 2003, issued as U.S. Pat. No. 7,128,825 on Oct. 31, 2005, which is incorporated herein by reference to the extent not inconsistent with the description and claimed aspects herein. An example of a suitable processing system is the Reflection LK Ecmp™ processing system, available from Applied Materials, Inc., of Santa Clara, Calif.

Polishing Processes

Methods and compositions are provided for polishing a substrate to remove residues and minimize dishing within features, while increasing throughput with a decrease in polishing time. The methods may be performed by an electrochemical polishing technique. In one aspect, the method may include processing a substrate having a conductive material layer disposed over features, supplying a polishing composition as described herein to the surface of the substrate, applying a pressure between the substrate and a polishing article, providing relative motion between the substrate and the polishing article, applying a bias between a first electrode and a second electrode in electrical contact with the substrate, and removing at least a portion of the conductive material from the substrate surface.

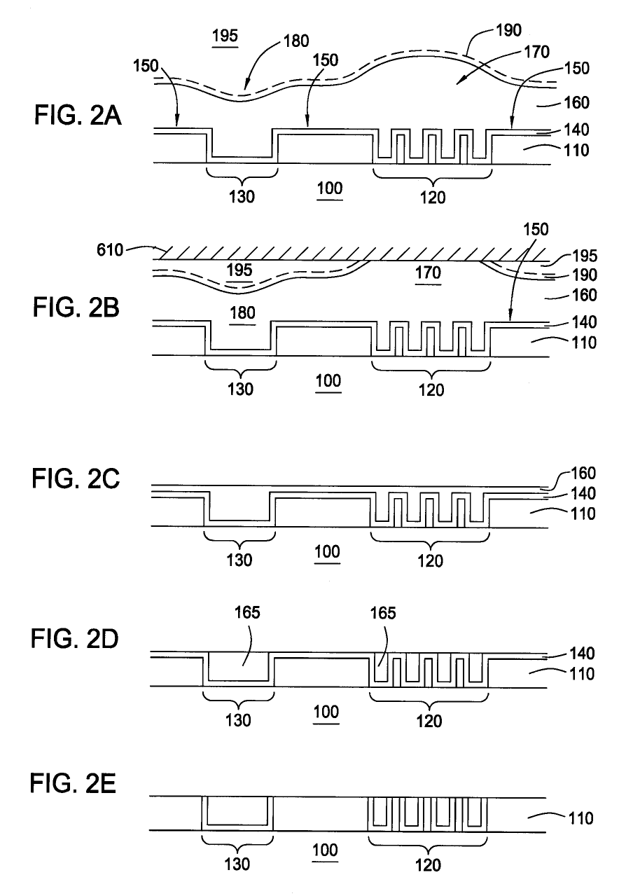

One embodiment of the process will now be described in reference to FIGS. 2A-2E, which are schematic cross-sectional views of a substrate being processed according to methods and compositions described herein. Referring to FIG. 2A, a substrate generally includes a dielectric layer 110 formed on a substrate 100. A plurality of apertures, such as vias, trenches, contacts, or holes, are patterned and etched into the dielectric layer 110, such as a dense array of narrow feature definitions 120 and low density of wide feature definitions 130. The apertures may be formed in the dielectric layer 110 by conventional photolithographic and etching techniques.

FIG. 2A depicts a substrate 100 and a conductive material 160 with a passivation layer 190 formed thereon before an Ecmp process has been applied. FIG. 2B illustrates the contact of the substrate surface with a polishing article to remove a portion of the passivation layer 190 formed thereon. FIG. 2C illustrates the substrate after a portion of the conductive material 160, such as at least about 50% of the conductive material 160, has been removed by applying a first Ecmp process. The remaining conductive layer 160 disposed upon a barrier layer 140 is removed to the barrier layer 140 by applying a second Ecmp process, as illustrated in FIG. 2D. Furthermore, as illustrated in FIG. 2E, the remaining barrier layer 140 on the dielectric layer 110 may be removed by a third process, such as a CMP process or a third Ecmp process. Alternatively, and not shown, the remaining conductive material 160 and the barrier layer material 140 may be removed in a single processing step.

The terms narrow and wide feature definitions may vary depending on the structures formed on the substrate surface, but can generally be characterized by the respective deposition profiles of excessive material deposition (or high overburden) formed over narrow feature definitions and minimal or low material deposition (minimal or low overburden), over wide feature definitions. For example narrow feature definitions may be about 0.13 μm in size and may have a high overburden as compared to wide feature definitions that may be about 10 μm in size and that may have minimal or insufficient overburden. However, high overburdens and low overburdens do not necessarily have to form over features, but may form over areas on the substrate surface between features.

The dielectric layer 110 may comprise one or more dielectric materials conventionally employed in the manufacture of semiconductor devices. For example, dielectric materials may include materials such as silicon dioxide, phosphorus-doped silicon glass (PSG), boron-phosphorus-doped silicon glass (BPSG), and silicon dioxide derived from tetraethyl orthosilicate (TEOS) or silane by plasma enhanced chemical vapor deposition (PECVD). The dielectric layer may also comprise low dielectric constant materials, including fluoro-silicon glass (FSG), polymers, such as polyamides, carbon-containing silicon oxides, such as BLACK DIAMOND™ dielectric material, silicon carbide materials, which may be doped with nitrogen and/or oxygen, including BLOK™ dielectric materials, available from Applied Materials, Inc. of Santa Clara, Calif.

A barrier layer 140 is disposed conformally in the feature definitions 120 and 130 and on the substrate 100. The barrier layer 140 may comprise metals or metal nitrides, such as tantalum, tantalum nitride, tantalum silicon nitride, titanium, titanium nitride, titanium silicon nitride, tungsten, tungsten nitride or combinations thereof, or any other material that may limit diffusion of materials between the substrate and/or dielectric materials and any subsequently deposited conductive materials.

A conductive material layer 160 is disposed on the barrier layer 140. The term “conductive material layer” as used herein is defined as any conductive material, such as copper, tungsten, aluminum, silver or an alloy thereof, used to fill a feature to form lines, contacts or vias. While not shown, a seed layer of a conductive material may be deposited on the barrier layer prior to the deposition of the conductive material layer 160 to improve interlayer adhesion and improve subsequent deposition processes. The seed layer may be of the same material as the subsequent material to be deposited.

One type of conductive material layer 160 comprises copper containing materials. Copper containing materials include copper, copper alloys (e.g., copper-based alloys containing at least about 80 weight percent copper) or doped copper. As used throughout this disclosure, the phrase “copper containing material,” the word “copper,” and the symbol “Cu” are intended to encompass copper, copper alloys, doped copper, or combinations thereof. Additionally, the conductive material may comprise any conductive material used in semiconductor manufacturing processing.

In one embodiment, the deposited conductive material layer 160 has a deposition profile of excessive material deposition or high overburden 170, also referred to as a hill or peak, formed over narrow feature definitions 120 and minimal overburden 180, also referred to as a valley, over wide feature definitions 130. In another embodiment, high overburdens and minimal overburdens are arbitrarily formed across the substrate surface between features.

An electrochemical mechanical polishing technique using a combination of chemical activity, mechanical activity and electrical activity to remove material and planarize a substrate surface may be performed as follows. In one embodiment of an electrochemical mechanical polishing technique, the substrate is disposed in a receptacle, such as a platen containing a first electrode and a polishing composition. The polishing composition forms a passivation layer on the substrate surface. The passivation layer may chemically and/or electrically insulate material disposed on a substrate surface.

A polishing article coupled to a polishing article assembly containing a second electrode is then disposed in the platen and physically contacted and/or electrically coupled with the substrate through the polishing article. Relative motion is provided between the substrate surface and the conductive article to reduce or remove the passivation layer. A bias from a power source is applied between the two electrodes. The bias may be applied by an electrical pulse modulation technique providing at least anodic dissolution. The bias may be transferred from a conductive article in the polishing article assembly to the substrate.

A first Ecmp process may be used to remove bulk conductive material from the substrate surface as shown from FIGS. 2B-2C and then a second Ecmp process to remove residual copper containing materials as shown from FIGS. 2C-2D. Bulk material is broadly defined herein as any material deposited on the substrate in an amount more than sufficient to substantially fill features formed on the substrate surface. Residual material is broadly defined as any bulk copper containing material remaining after one or more polishing process steps. Generally, the bulk removal during a first Ecmp process removes at least about 50% of the conductive layer, preferably at least about 70%, more preferably at least about 80%, for example, at least about 90%. The residual removal during a second Ecmp process removes most, if not all the remaining conductive material disposed on the barrier layer to leave behind the filled plugs. In an alternative embodiment of the Ecmp process, the entire conductive material may be removed from the substrate surface in a single processing step.

The first Ecmp process attributes to the throughput of substrate manufacturing due to a fast removal rate of the conductive layer. However, if the first Ecmp process is used solely, too much conductive material may be removed to produce an under burden. The second Ecmp process attributes to the throughput of substrate manufacturing due to the precise removal the conductive layer to form level substrate surfaces. Therefore, the combined first and second Ecmp processes increases throughput and produces high quality planar substrate surfaces.

The bulk removal Ecmp process may be performed on a first polishing platen and the residual removal Ecmp process on a second polishing platen of the same or different polishing apparatus as the first platen. In another embodiment, the residual removal Ecmp process may be performed on the first platen. Any barrier material may be removed on a separate platen, such as the third platen. For example, an apparatus in accordance with the processes described herein may include three platens for removing bulk material or comprise one platen to remove bulk material, a second platen for residual removal and a third platen for barrier removal, wherein the bulk and the residual processes are Ecmp processes and the barrier removal is a CMP process. In another embodiment, three Ecmp platens may be used to remove bulk material, residual removal and barrier removal.

The Ecmp process begins by positioning the substrate in a polishing apparatus and exposed to a polishing composition 195 that can form a passivation layer 190 on the conductive material layer. The passivation layer may be formed by the polishing compositions described herein.

Although the polishing compositions are particularly useful for removing copper, it is believed that the polishing compositions also may be used for the removal of other conductive materials, such as aluminum, platinum, tungsten, titanium, titanium nitride, tantalum, tantalum nitride, cobalt, gold, silver, ruthenium or combinations thereof. Mechanical abrasion, such as from contact with the conductive polishing article may be used with the polishing composition to improve planarity and improve removal rate of these conductive materials.

Suitable polishing compositions that may be used with the processes described herein are as follows. A polishing composition for the bulk and/or residual polishing step may include an acid based electrolyte, a corrosion inhibitor selected from the group of an amino acid based inhibitor, a polymeric based corrosion inhibitor, an oxidizer, a chelating inhibitor or combinations thereof, a pH adjusting agent, a solvent, and a pH between about 1 and about 10. Alternatively, the polishing composition may include an acid based electrolyte, a corrosion inhibitor selected from the group of a cathodic inhibitor, an anodic inhibitor, or a mixed cathodic and anodic inhibitor, a pH adjusting agent, a solvent, and a pH between about 1 and about 10. The polishing composition may also include abrasive particulates.

Although the polishing compositions are particularly useful for removing copper, it is believed that the polishing compositions also may be used for the removal of other conductive materials, such as aluminum, platinum, tungsten, titanium, titanium nitride, tantalum, tantalum nitride, cobalt, gold, silver, ruthenium and combinations thereof.

The polishing composition includes an acid based electrolyte system for providing electrical conductivity. Suitable acid based electrolyte systems include, for example, phosphoric acid based electrolytes, sulfuric acid, nitric acid, perchloric acid, acetic acid, citric acid, salts thereof and combinations thereof. Suitable acid based electrolyte systems include an acid electrolyte, such as phosphoric acid, boric acid and/or citric acid, as well as acid electrolyte derivatives, including ammonium, potassium, sodium, calcium and copper salts thereof. The acid based electrolyte system may also buffer the composition to maintain a desired pH level for processing a substrate.

Examples of suitable acid based electrolytes include compounds having a phosphate group (PO₄⁻³), such as, phosphoric acid, copper phosphate, potassium phosphates (K_{X}H_{(3-X)}PO₄) (x=1, 2 or 3), such as potassium dihydrogen phosphate (KH₂PO₄), dipotassium hydrogen phosphate (K₂HPO₄), ammonium phosphates ((NH₄)_{X}H_{(3-X)}PO₄) (x=1, 2 or 3), such as ammonium dihydrogen phosphate ((NH₄)H₂PO₄), diammonium hydrogen phosphate ((NH₄)₂HPO₄), compounds having a nitrite group (NO₃¹⁻), such as, nitric acid or copper nitrate, compounds having a boric group (BO₃³⁻), such as, orthoboric acid (H₃BO₃) and compounds having a sulfate group (SO₄²⁻), such as sulfuric acid (H₂SO₄), ammonium hydrogen sulfate ((NH₄)HSO₄), ammonium sulfate, potassium sulfate, copper sulfate, derivatives thereof and combinations thereof. The invention also contemplates that conventional electrolytes known and unknown may also be used in forming the composition described herein using the processes described herein.

The acid based electrolyte system may contains an acidic component that can take up about 1 and about 30 percent by weight (wt %) or volume (vol %) of the total composition of solution to provide sufficient conductivity as described herein for practicing the processes described herein. Examples of acidic components include dihydrogen phosphate and/or diammonium hydrogen phosphate and may be present in the polishing composition in amounts between about 15 wt % and about 25 wt %. Alternately, phosphoric acid may be present in concentrations up to 30 wt %, for example, between about 2 wt % and about 6 wt %. The acid based electrolyte may also be added in solution, for example, the 6 wt. % of phosphoric acid may be from 85% aqueous phosphoric acid solution for an actual phosphoric acid composition of about 5.1 wt. %.

The polishing composition may include a corrosion inhibitor. The corrosion inhibitor may be selected from the group of an amino acid based inhibitor, a polymeric based corrosion inhibitor, an oxidizer, a chelating inhibitor or combinations thereof. Alternatively, the corrosion inhibitor may comprise a cathodic inhibitor, an anodic inhibitor, or a mixed cathodic and anodic inhibitor. The polishing composition may have corrosion inhibitor concentration between about 0.01 weight percent (wt. %) and about 5 wt. % of the composition, such as between about 0.1 weight percent (wt. %) and about 0.5 wt. %.

The amino acid corrosion inhibitor includes a compound having a carboxylic functional group and an amine functional group. The chelating agent may have multiple carboxylic groups, and may also include additional structures including nitrogen containing rings and sulfur atoms. Examples of suitable amino acid corrosion inhibitors include histidine, cysteine, cystine, glycine and combinations thereof. The amino acid corrosion inhibitor further includes salts of amino acids, for example, calcium, sodium, ammonia and potassium salts of amino acids. The amino acid corrosion inhibitors are believed to form a passivation layer of a chelated substrate surface that inhibits electrical conductivity between the substrate and surrounding composition.

Polymeric based corrosion inhibitors may be electrically resistive additives that reduce the conductivity of the conductive material of the polishing surface. Examples of polymeric based corrosion inhibitors are polyacrylamide, polyacrylic acid polymers, polycarboxylic copolymers, coconut diethanolamide, oleic diethanolamide, ethanolamide derivatives, or combinations thereof.

Suitable polymeric based corrosion inhibitors also include compounds having a nitrogen atom, an oxygen atom, or a combination of the two. Polymeric based corrosion inhibitors include aziridine compounds, including propyleneimine and ethyleneimineimine (C₂H₅N) based polymeric materials, such as polyethyleneimine imine (PEI) having a molecular weight between about 400 and about 1,000,000 comprising (—CH₂—CH₂—NH—) monomer units, ethyleneimine glycol (C₂H₆O₂) based polymeric materials, such as polyethyleneimine glycol (PEG) having a molecular weight between about 200 and about 100,000 comprising (OCH₂CH₂)N monomer units, or combinations thereof. Polyamine and polyimide polymeric material may also be used as polymeric based corrosion inhibitors in the composition. Other suitable polymeric based corrosion inhibitors include oxide polymers, such as, polyethyleneoxide, polypropylene oxide and ethyleneimine oxide/propylene oxide co-polymer (EO/PO), with a molecular weight range between about 200 and about 100,000.

Additionally, the polymeric based corrosion inhibitors may comprise polymers of heterocyclic compounds containing nitrogen and/or oxygen atoms, such as polymeric materials derived from monomers of pyridine (C₅H₅N), pyrrole (C₄H₅N), furan (C₄H₄O), purine (C₅H₄N₄), or combinations thereof. The polymeric based corrosion inhibitors may also include polymers with both linear and heterocyclic structural units containing nitrogen and/or oxygen atoms, such as a heterocyclic structural units and amine or ethyleneimine imine structural units. The polymeric based corrosion inhibitors may also include carbon containing functional groups or structural units, such as homocyclic compounds, such as benzyl or phenyl functional groups, and linear hydrocarbons suitable as structural units or as functional groups to the polymeric backbone. A mixture of the polymeric based corrosion inhibitors described herein is also contemplated, such as a polymeric mixture of a heterocyclic polymer material and an amine or ethyleneimine imine polymeric material (polyethyleneimine imine). An example of a suitable polymeric based corrosion inhibitor includes XP-1296 (also known as L-2001), containing a heterocyclic polymer/polyamine polymer, commercially available from Rohm and Hass Electronic Materials of Marlborough, Mass., and Compound S-900, commercially available from Enthone-OMI Inc., of New Haven, Conn.

Some polymeric based corrosion inhibitor may be added the composition in a solution, for example, the polishing composition may include 0.5 wt. % PEI with a 2,000 molecular weight of a 5% aqueous PEI solution and/or 0.5 wt. % XP-1296 (or XP tradename family of compounds from Rohm and Haas) with a 2000 molecular weight of a 10% aqueous XP-1296 solution. Thus, the invention contemplates that the percentages of all of the components, including the polymeric based corrosion inhibitors, reflect both dilute compounds provided from their manufacturing source as well as the actual present amount of the component. For example, 6% phosphoric acid may also be present as 5.1%, or 6% of the 85% phosphoric acid solution available from phosphoric acid manufacturers. Where possible, the actual amount of the component of the composition has been provided.

While not being limited to any particular theory, it is believed that a lone pair of electrons in the polymer's functional groups which include nitrogen atom or oxygen atom interact with the copper material on the surface to form a passivation layer. A corrosion inhibitor having a nitrogen atom may also contribute to forming the passivation layer with the polymeric passivation material. Chelating agents that have a donor electron or a lone pair of electrons may also contribute to the formation of the passivation layer in a similar manner. The passivation layer formed from the second polishing composition may mechanically interact with the exposed conductive material by forming a viscous layer that inhibits fluid flow, or mass transportation, of polishing composition to and from the exposed conductive material. The viscous layer may be formed from a phosphoric acid or phosphoric acid derivative. This inhibiting flow can be effective in reducing removal of copper material in recessed areas.

The corrosion inhibitor may also comprise an inorganic oxidizer and/or a compound containing an element in its highest oxidation state. Examples of suitable oxidizers include inorganic salts periodic acid, periodate salts, perbromic acid, perbromate salts, perchloric acid, perchloric salts, perbonic acid, nitrate salts (such as cerium nitrate, iron nitrate, ammonium nitrate), ferrates, perborate salts and permanganates. Other oxidizers include bromates, chlorates, chromates, iodates, iodic acid, and cerium (IV) compounds such as ammonium cerium nitrate. The inorganic acid salts are believed to form a passivation layer of an oxidized and/or chelated substrate surface that inhibits electrical conductivity between the substrate and surrounding composition.

A chelating agent may be used to form a chelated substrate surface to inhibitor the conductivity of the substrate surface by binding to a conductive material on the substrate surface. The plurality of chelating agents includes at least a chelating agent having a carboxylic group or a chelating agent having an amine or amide functional group. The chelating agent having a carboxylic group include compounds having one or more functional groups selected from the group of carboxylic groups, dicarboxylic groups, tricarboxylic groups, a mixture of hydroxyl and carboxylic groups, or combinations thereof. The one or more chelating agents may also include salts of the chelating agents described herein, for example, ammonia and potassium salts thereof. Alternatively, the chelating agent may comprise a hydroxyl group, such as in ammonium hydroxide.

Examples of suitable chelating agents having one or more carboxylic groups include citric acid, tartaric acid, succinic acid, oxalic acid, ethyleneiminediaminetetraacetic acid (EDTA), salts thereof, or combinations thereof. Other suitable chelating agents having one or more carboxylic groups include acetic acid, adipic acid, butyric acid, capric acid, caproic acid, caprylic acid, glutaric acid, glycolic acid, formic acid, fumaric acid, lactic acid, lauric acid, malic acid, maleic acid, malonic acid, myristic acid, plamitic acid, phthalic acid, propionic acid, pyruvic acid, stearic acid, valeric acid, derivatives thereof, salts thereof or combinations thereof. For example, suitable salts for the chelating agent may include ammonium citrate, potassium citrate, ammonium succinate, potassium succinate, ammonium oxalate, potassium oxalate, potassium tartrate, or combinations thereof. The salts may have multi-basic states, for example, citrates have mono-, di- and tri-basic states. Example of amino acid salts include calcium acetate (Ca(O₂CCH₃)₂), Na₂EDTA, Na₄EDTA, K₄EDTA or Ca₂EDTA.

The chelating agent having an amine or amide functional group can include compounds such as ethyleneiminediamine (EDA), diethyleneiminetriamine, diethyleneiminetriamine derivatives, hexadiamine, amino acids, glycine, methylformamide, derivatives thereof, salts thereof or combinations thereof.

Alternatively, the corrosion inhibitor may be selected from the group of a cathodic inhibitor, an anodic inhibitor, or a mixed cathodic and anodic inhibitor.

A cathodic inhibitor is used in the composition to prevent or minimize corrosion of the cathode, which may for example be composed of steel. Cathodic inhibitor may carry a positive charge in the polishing composition. The mechanism of cathodic inhibitors involves interfering with the hydrogen discharge reaction in an acid solution and/or restricting the access of reducible species, such as oxygen, to the metal surface by two methods. In a first method, the corrosion inhibitor may remove reducible species, e.g., oxygen, by reaction with the reducible species in the composition to limit the cathodic reaction itself thereby reducing or minimizing reducible species capable of reaction. Both water and free hydrogen (H+) can perform this function.

In a second method, the cathodic inhibitor may precipitate a film that inhibits diffusion of reducible species. For example, polymeric materials with a positive charge attracted to the cathode and phosphates can form a diffusion barrier to oxygen diffusion and/or a chemical barrier, a surface impedance mechanism, to minimize reducible species, e.g., oxygen, interaction with material comprising the cathode. Such barrier may be in the form of visible, gel-like films on the cathode surface. The gel-like films are generally less adherent and less compact than those formed by anodic inhibitors on anodic materials. Examples of cathodic inhibitors for use with the compositions described herein include hydroxides, phosphates, polymeric phosphates from dehydration of phosphoric acid (polyphosphates) carbonates, and polymer chemistries such as polyethyleneimine glycol and polyethyleneimineimine in different molecular weights.

Anodic inhibitors may comprise compounds with negative charges in the solution including the corrosion inhibitors as mentioned above that would have a negative charge or form a compound with a negative charge in the polishing composition. Anodic inhibitors are attracted to the anode and may interact with the anodic surface. Anodic inhibitors, also known as absorption inhibitors, may comprise organic substances including amine compounds, quinoline compounds or thiourea compounds. One example of an anodic inhibitor is ethyleneiminediamine. Ethyleneiminediamine may be an absorption inhibitor in the composition having phosphoric acid in a wide pH range (3-10). Further examples of anodic inhibitors include polyethyleneimine glycol and derivatives thereof with negative charges. It is believed that the anodic inhibitors of the compositions prevent anode conductive articles or components of conductive articles from being etched away while providing a basis or current to a metal substrate in contact therewith. For example, polishing articles may include soft metals, conductive fillers, fibers coated with a conductive material, or combinations thereof, which may be disposed in a binder material, and that exposed conductive material may be susceptible to an anodic dissolution process. Additionally, while the anodic and cathodic inhibitors are described as reacting more likely with the respective anode or cathode, the invention contemplates that the respective inhibitors may react with the opposing electrode.

The invention also contemplates using a corrosion inhibitor that has both a cathodic component, positive charge, and an anodic component, a negative charge. One example of such a compound is polyethyleneimineimine in an acidic pH (less than pH 7). The mixed charge corrosion inhibitors can be used to stabilize adsorbed anionic layer for conductive article passivation.

One or more pH adjusting agents is preferably added to the polishing composition to achieve a pH between about 2 and about 10, and preferably an acidic pH between about 3 and less than about 7, for example at a pH between about 4 and about 6. The amount of pH adjusting agent can vary as the concentration of the other components is varied in different formulations, but in general the total solution may include up and about 70 wt % of the one or more pH adjusting agents, but preferably between about 0.2% and about 25% by volume. Different compounds may provide different pH levels for a given concentration, for example, the composition may include between about 0.1% and about 10% by volume of a base, such as potassium hydroxide, ammonium hydroxide, sodium hydroxide or combinations thereof, providing the desired pH level. The one or more pH adjusting agents may be added the composition in a solution, for example, the polishing composition may include potassium hydroxide (KOH) of a 40% or 45% water solution. The one or more pH adjusting agents can be chosen from inorganic acids including phosphoric acid, sulfuric acid, hydrochloric, nitric acid, derivatives thereof and combinations thereof.

The balance or remainder of the polishing compositions described herein is a solvent, such as a polar solvent, including water, preferably deionized water. Other solvent may be used solely or in combination with water, such as organic solvents. Organic solvents include alcohols, such as methyl alcohol, ethyl alcohol, isopropyl alcohol or glycols, ethers, such as diethyl ether, furans, such as tetrahydrofuran, hydrocarbons, such as pentane or heptane, aromatic hydrocarbons, such as benzene or toluene, halogenated solvents, such as methyleneimine chloride or carbon tetrachloride, derivatives, thereof or combinations thereof.

Optionally, abrasive particles may be used to improve the surface finish and removal rate of conductive materials from the substrate surface during polishing. The addition of abrasive particles to the polishing composition can allow the final polished surface to achieve a surface roughness of that comparable with a conventional CMP process even at low pad pressures. Surface finish, or surface roughness, has been shown to have an effect on device yield and post polishing surface defects. Abrasive particles may comprise up and about 30 wt % of the polishing composition during processing. A concentration between about 0.001 wt % and about 5 wt % of abrasive particles may be used in the polishing composition.

Suitable abrasives particles include inorganic abrasives, polymeric abrasives, and combinations thereof. Inorganic abrasive particles that may be used in the electrolyte include, but are not limited to, silica, alumina, zirconium oxide, titanium oxide, cerium oxide, germania, or any other abrasives of metal oxides, known or unknown. Generally, suitable inorganic abrasives have a Mohs hardness of greater than 6, although the invention contemplates the use of abrasives having a lower Mohs hardness value. The polymeric abrasives may comprise abrasive polymeric materials. Examples of polymeric abrasives materials include polymethylmethacrylate, polymethyl acrylate, polystyrene, polymethacrylonitrile, and combinations thereof. The polymeric abrasives may have a Hardness Shore D of between about 60 and about 80, but can be modified to have greater or lesser hardness value.

The polymeric abrasives may be modified to have one or more functional groups that can bind to the conductive material or conductive material ions, thereby facilitating the electrochemical mechanical polishing removal of material from the surface of a substrate. For example, if copper is to be removed in the polishing process, the organic polymer particles can be modified to have an amine group, a carboxylic group, a pyridine group, a hydroxide group, all ligands with a high affinity for copper, or combinations thereof, to bind the removed copper as substitutes for or in addition to the chemically active agents in the polishing composition, such as the chelating agents or corrosion inhibitors. The functional groups can bind to the metal material(s) on the substrate surface to help improve the uniformity and surface finish of the substrate surface. Alternatively, inorganic particles coated with the polymeric materials described herein may also be used with the polishing composition. It is within the scope of the current invention for the polishing composition to contain polymeric abrasives, inorganic abrasives, the polymeric coated inorganic abrasives, and any combination thereof depending on the desired polishing performance and results.

The polishing compositions described herein may include one or more additive compounds. Additive compounds include electrolyte additives including, but not limited to, suppressors, enhancers, levelers, brighteners, stabilizers, and stripping agents to improve the effectiveness of the polishing composition in polishing of the substrate surface. For example, certain additives may decrease the ionization rate of the metal atoms, thereby inhibiting the dissolution process, whereas other additives may provide a finished, shiny substrate surface. The additives may be present in the polishing composition in concentrations up and about 15% by weight or volume, and may vary based upon the desired result after polishing.

Further examples of additives to the polishing composition are more fully described in U.S. patent application Ser. No. 10/141,450, filed on May 7, 2002, which is incorporated by reference herein to the extent not inconsistent with the claimed aspects and disclosure herein.

Ecmp solutions of varying compositions may be used to remove bulk material and residual material, such as copper and/or copper alloys, as well as to remove barrier materials, such as tantalum nitrides or titanium nitrides. Specific formulations of the polishing compositions are used to remove the particular materials. Polishing compositions utilized during embodiments herein are advantageous for Ecmp processes. Generally, Ecmp solutions are much more conductive than traditional CMP solutions. The Ecmp solutions have a conductivity of about 10 mS/cm or higher, while traditional CMP solutions have a conductivity from about 3 mS/cm to about 5 mS/cm. The conductivity of the Ecmp solutions greatly influences that rate at which the Ecmp process advances, i.e., more conductive solutions have a faster material removal rate. The compositions formed herein may generally have a conductivity between about 10 mS/cm and about 80 mS, such as between about 30 mS/cm and about 50 mS, for example, about 40 mS/cm. The composition may be adjusted in conductivity based on the process being performed. For removing bulk material, the Ecmp solution has a conductivity of about 10 mS/cm or higher, preferably in a range from about 30 mS/cm to about 60 mS/cm. For residual material, the Ecmp solution has a conductivity of about 10 mS/cm or higher, preferably in a range from about 15 mS/cm to about 40 mS/cm.

The substrate is exposed to a polishing composition described herein that forms a passivation layer 190 on the conductive material layer 160. The passivation layer 190 forms on the exposed conductive material 160 on the substrate surface including the high overburden 170, peaks, and minimal overburden 180, valleys, formed in the deposited conductive material 160. The passivation layer 190 chemically and/or electrically insulates the surface of the substrate from chemical and/or electrical reactions. The passivation layer is formed from the exposure of the substrate surface to the corrosion inhibitor and/or other materials capable of forming a passivating or insulating film, for example, chelating agents. The thickness and density of the passivation layer can dictate the extent of chemical reactions and/or amount of anodic dissolution. For example, a thicker or denser passivation layer 190 has been observed to result in less anodic dissolution compared to thinner and less dense passivation layers. Thus, control of the composition of passivating agents, corrosion inhibitors and/or chelating agents, allow control of the removal rate and amount of material removed from the substrate surface.

FIG. 2B illustrates electrochemical mechanical polishing during processing. During processing, the substrate surface and a polishing article, such as conductive polishing article 610, are contacted with one another and moved in relative motion to one another, such as in a relative orbital motion, to remove portions of the passivation layer 190 formed on the exposed conductive material 160, which contact may additionally also remove a portion of the underlying conductive material 160.

The substrate surface and polishing article 610 are contacted at a pressure less than about 2 pounds per square inch (lb/in² or psi) (13.8 kPa). Removal of the passivation layer 190 and some conductive material 160 may be performed with a process having a pressure of about 1 psi (6.9 kPa) or less, for example, from about 0.01 psi (69 Pa) to about 0.5 psi (3.4 kPa). In one aspect of the process, the substrate surface and polishing article are contacted at a pressure of about 0.2 psi (1.4 kPa) or less.

The polishing pressures used herein reduce or minimize damaging shear forces and frictional forces for substrates containing low k dielectric materials. Reduced or minimized forces can result in reduced or minimal deformations and defect formation of features from polishing. Further, the lower shear forces and frictional forces have been observed to reduce or minimize formation of topographical defects, such as dishing and scratches, and delamination, during polishing. Contact between the substrate and a conductive polishing article also allows for electrical contact between the power source and the substrate by coupling the power source to the polishing article when contacting the substrate. A region of non-passivated material may be exposed and removed by anodic dissolution by mechanical abrasion to disturb or remove the passivation layer on the surface of the substrate.

In one embodiment the platen is rotated at a velocity from about 3 rpm (rotations per minute) to about 100 rpm, and the polishing head is rotated at a velocity from about 5 rpm to about 200 rpm and also moved linearly at a velocity from about 5 cm/s (centimeters per second) to about 25 cm/s in a direction radial to the platen. The preferred ranges for a 200 mm diameter substrate are a platen rotational velocity from about 5 rpm to about 40 rpm and a polishing head rotational velocity from about 7 rpm to about 100 rpm and a linear (e.g., radial) velocity of about 10 cm/s. The preferred ranges for a 300 mm diameter substrate are a platen rotational velocity from about 5 rpm to about 20 rpm and a polishing head rotational velocity from about 7 rpm to about 50 rpm and a linear (e.g., radial) velocity of about 10 cm/s. In one embodiment of the present invention the platen has a diameter between about 17 inches (43.2 cm) and about 30 inches (76.2 cm). The polishing head may move along the radius of the platen for a distance between about 0.1 inches (2.5 mm) and about 2 inches (5.1 cm). The carrier head rotational speed may be greater than a platen rotational speed by a ratio of carrier head rotational speed to platen rotational speed of greater than about 1:1, such as a ratio of carrier head rotational speed to platen rotational speed between about 1.5:1 and about 12:1, for example between about 1.5:1 and about 3:1, to remove material from the substrate surface.

A bias is applied to the substrate during contact between the substrate surface and the conductive polishing article for anodic dissolution of the conductive material 160 from the substrate surface. The bias is generally provided to produce anodic dissolution of the conductive material from the surface of the substrate at a current density up to about 100 mA/cm² which correlates to an applied current of about 40 amps to process substrates with a diameter up to about 300 mm. For example, a 200 mm diameter substrate may have a current density from about 0.01 mA/cm² to about 50 mA/cm², which correlates to an applied current from about 0.01 A to about 20 A. The invention also contemplates that the bias may be applied and monitored by volts, amps and watts. For example, in one embodiment, the power supply may apply a power between about 0.1 watts and 100 watts, a voltage between about 0.1 V and about 10 V, and a current between about 0.1 amps and about 10 amps.

During anodic dissolution under application of the bias, the substrate surface, i.e., the conductive material layer 160 may be biased anodically above a threshold potential of the conductive material, for example, a metal material, on the substrate surface to “oxidize”. When a metal material oxidizes, a metal atom gives up one or more electrons to the power source and forms metal ions or cations. The metal ions may then leave the substrate surface and dissolve into the electrolyte solution. In the case where copper is the desired material to be removed, cations can have the Cu¹⁺ or Cu²⁺ oxidation state.

The metal ions may also contribute to the formation of the thickness and/or density of the passivation layer 190. For example, the inhibitors and/or chelating agents found in the polishing composition may complex with the metal ions and the metal ions become incorporated into the passivation layer 190. Thus, the presence of the inhibitors and/or chelating agents found in the polishing composition limit or reduce the electrochemical dissolution process of the metal ions into the electrolyte, and further incorporate such metal ions into the passivation layer 190. It has been observed that the thickness and/or density of the undisturbed passivation layer may increase after periods of applied bias for anodic dissolution of conductive materials on the substrate surface. It is believed that the increase in the thickness and/or density of the undisturbed passivation layer is related to the total applied power and is a function of time and/or power levels. It has also been observed that the undisturbed passivation layer incorporates metal ions and that the metal ions may contribute to the thickness and/or density of the passivation layer.

The bias may be varied in power and application depending upon the user requirements in removing material from the substrate surface. For example, increasing power application has been observed to result in increasing anodic dissolution. The bias may also be applied by an electrical pulse modulation technique. Pulse modulation techniques may vary, but generally include a cycle of applying a constant current density or voltage for a first time period, then applying no current density or voltage or a constant reverse current density or voltage for a second time period. The process may then be repeated for one or more cycles, which may have varying power levels and durations. The power levels, the duration of power, an “on” cycle, and no power, an “off” cycle” application, and frequency of cycles, may be modified based on the removal rate, materials to be removed, and the extent of the polishing process. For example, increased power levels and increased duration of power being applied have been observed to increase anodic dissolution.

In one pulse modulation process for electrochemical mechanical polishing, the pulse modulation process comprises an on/off power technique with a period of power application, “on”, followed by a period of no power application, “off”. The on/off cycle may be repeated one or more times during the polishing process. The “on” periods allow for removal of exposed conductive material from the substrate surface and the “off” periods allow for polishing composition components and by-products of “on” periods, such as metal ions, to diffuse to the surface and complex with the conductive material. During a pulse modulation technique process it is believed that the metal ions migrate and interact with the corrosion inhibitors and/or chelating agents by attaching to the passivation layer in the non-mechanically disturbed areas. The process thus allows etching in the electrochemically active regions, not covered by the passivation layer, during an “on” application, and then allowing reformation of the passivation layer in some regions and removal of excess material during an “off” portion of the pulse modulation technique in other regions. Thus, control of the pulse modulation technique can control the removal rate and amount of material removed from the substrate surface.

The “on”/“off” period of time may be between about 1 second and about 60 seconds each, for example, between about 2 seconds and about 25 seconds, and the invention contemplates the use of pulse techniques having “on” and “off” periods of time greater and shorter than the described time periods herein. In one example of a pulse modulation technique, power is applied between about 16% and about 66% of each cycle.

Non-limiting examples of pulse modulation technique with an on/off cycle for electrochemical mechanical polishing of materials described herein include: applying power, “on”, between about 5 seconds and about 10 seconds and then not applying power, “off”, between about 2 seconds and about 25 seconds; applying power for about 10 seconds and not applying power for 5 seconds, or applying power for 10 seconds and not applying power for 2 seconds, or even applying power for 5 seconds and not applying power for 25 seconds to provide the desired polishing results. The cycles may be repeated as often as desired for each selected process. One example of a pulse modulation process is described in commonly assigned U.S. Pat. No. 6,379,223, which is incorporated by reference herein to the extent not inconsistent with the claimed aspects and disclosure herein. Further examples of a pulse modulation process is described in co-pending U.S. Ser. No. 10/611,805, entitled “Effective Method To Improve Surface Finish In Electrochemically Assisted Chemical Mechanical Polishing,” filed on Jun. 30, 2003, which is incorporated by reference herein to the extent not inconsistent with the claimed aspects and disclosure herein.

A removal rate of conductive material of up to about 15,000 Å/min can be achieved by the processes described herein. Higher removal rates are generally desirable, but due to the goal of maximizing process uniformity and other process variables (e.g., reaction kinetics at the anode and cathode) it is common for dissolution rates to be controlled from about 100 Å/min to about 15,000 Å/min. In one embodiment of the invention where the copper material to be removed is less than 5,000 Å thick, the voltage (or current) may be applied to provide a removal rate from about 100 Å/min to about 5,000 Å/min. The substrate is typically exposed to the polishing composition and power application for a period of time sufficient to remove at least a portion or all of the desired material disposed thereon.

In one embodiment of the Ecmp process, the removal rate of conductive material 160 is much faster during the first Ecmp process than during the second Ecmp process. For example, the first Ecmp process removes conductive material 160 at a rate from about 1,000 Å/min to about 15,000 Å/min, while the second Ecmp process removes conductive material 160 at a rate from about 100 Å/min to about 8,000 Å/min. The second Ecmp process is slower in order to prevent excess metal removal to form topographical defects, such as concavities or depressions known as dishing 55, as shown in FIG. 2B. Therefore, a majority of the conductive material 160 is removed at a faster rate during the first Ecmp process than the remaining conductive layer 160 during the second Ecmp process. The two-step Ecmp process increases throughput of the total substrate processing and while producing a smooth surface with little or no defects.

Mechanical abrasion by a conductive polishing article removes the passivation layer that insulates or suppresses the current for anodic dissolution, such that areas of high overburden is preferentially removed over areas of minimal overburden as the passivation layer is retained in areas of minimal or no contact with the conductive polishing article. The removal rate of the conductive material 160 covered by the passivation layer is less than the removal rate of conductive material without the passivation layer. As such, the excess material disposed over narrow feature definitions 120 and the substrate field 150 is removed at a higher rate than over wide feature definitions 130 still covered by the passivation layer 190.

FIG. 2C illustrates that at least about 50% of the conductive material 160 was removed after the bulk removal of the first Ecmp process, for example, about 90%. After the first Ecmp process, conductive material 160 may still include the high overburden 170, peaks, and/or minimal overburden 180, valleys, but with a reduced proportionally size. However, conductive material 160 may also be rather planar across the substrate surface (not shown).

Referring to FIG. 2D, most, if not all of the conductive layer 160 is removed to expose barrier layer 140 and conductive trenches 165 by polishing the substrate with a second Ecmp process including a second Ecmp polishing composition. The conductive trenches 165 are formed by the remaining conductive material 160. The second polishing step may be performed under the processing parameters described herein and the second polishing composition may comprise a polishing composition formulated with the components described herein. One example of a second polishing step and composition for the second polishing step is disclosed in commonly assigned and co-pending U.S. Ser. No. 11/123,274, filed May 5, 2005, and published as US 20050218010, which is incorporated herein to the extent not inconsistent with the claims aspects and disclosure herein. Alternatively, the conductive material 160 may be removed to the barrier layer as shown in FIG. 2D is a single Ecmp polishing step with the polishing composition disclosed herein by the processing parameters described herein.

The barrier material, and alternatively, any further residual conductive material, may then be polished by a third polishing step to provide a planarized substrate surface containing conductive trenches 165, as depicted in FIG. 2E. The residual conductive material and barrier material may be removed by a third polishing process, such as a third Ecmp process or a CMP process. An example of a copper polishing process is disclosed in U.S. Pat. No. 6,790,768 and an example of a barrier polishing process is disclosed in commonly assigned and co-pending U.S. Ser. No. 10/193,810, filed Jul. 11, 2002, and published as US 20030013306, which are both incorporated herein to the extent not inconsistent with the claims aspects and disclosure herein.

After conductive material and barrier material removal processing steps, the substrate may then be buffed to minimize surface defects. Buffing may be performed with a soft polishing article, i.e., a hardness of about 40 or less on the Shore D hardness scale as described and measured by the American Society for Testing and Materials (ASTM), headquartered in Philadelphia, Pa., at reduced polishing pressures, such as about 2 psi or less. An example of a suitable buffing process and composition is disclosed in U.S. Pat. No. 6,858,540, issued on Dec. 8, 2002, and incorporated herein by reference to the extent not inconsistent with the invention.

Optionally, a cleaning solution may be applied to the substrate after each of the polishing process to remove particulate matter and spent reagents from the polishing process as well as help minimize metal residue deposition on the polishing articles and defects formed on a substrate surface. An example of a suitable cleaning solution is ELECTRACLEAN™ commercially available from Applied Materials, Inc., of Santa Clara, Calif.

Finally, the substrate may be exposed to a post polishing cleaning process to reduce defects formed during polishing or substrate handling. Such processes can minimize undesired oxidation or other defects in copper features formed on a substrate surface. An example of such a post polishing cleaning is the application of ELECTRACLEAN™, commercially available from Applied Materials, Inc., of Santa Clara, Calif.

It has been observed that substrate planarized by the processes described herein have exhibited reduced topographical defects, such as dishing, reduced residues, improved planarity, and improved substrate finish. The processes described herein may be further disclosed by the examples as follows.

While the foregoing is directed to embodiments of the present invention, other and further embodiments of the invention may be devised without departing from the basic scope thereof, and the scope thereof is determined by the claims that follow.

What is claimed is:

1. A method of electrochemically processing a substrate using a conductive polishing article, comprising:
disposing a substrate having a conductive material layer formed thereon in a process apparatus comprising a cathode coupled to the conductive polishing article and an anode, wherein the substrate is in electrical contact with the anode;
supplying a polishing composition comprising a cathodic inhibitor and an anodic inhibitor;
forming a protective film on the cathode to prevent corrosion of the cathode; and
polishing the substrate.

2. The method of claim 1, further comprising forming a protective film on the anode to prevent corrosion of the anode.

3. The method of claim 1, wherein the cathodic inhibitor is selected from the group comprising hydroxides, phosphates, polyphosphates, carbonates, polyethyleneimine glycol, and polyethyleneimine.

4. The method of claim 1, wherein the anodic inhibitors are selected from the group comprising amine compounds, quinoline compounds, and thiourea compounds.

5. The method of claim 1, wherein the cathode comprises steel.

6. The method of claim 1, wherein the cathodic inhibitor reacts with reducible species in the composition to limit the cathodic reaction itself thereby reducing or minimizing reducible species within the polishing composition.

7. The method of claim 1, wherein the protective film inhibits the diffusion of reducible species.

8. The method of claim 1, wherein the film comprises a gel.

9. The method of claim 1, wherein the polishing composition further initially comprises:
an acid based electrolyte;
a solvent; and
a pH between about 1 and about 10.

10. A method of electrochemically processing a substrate using a conductive polishing article, comprising:
disposing a substrate having a conductive material layer formed thereon in a process apparatus comprising a first electrode and a second electrode, wherein the substrate is in electrical contact with the second electrode;
providing a polishing composition between the first electrode and the substrate, wherein the polishing composition initially comprises:
an acid based electrolyte;
a corrosion inhibitor selected from the group of an amino acid based inhibitor, a polymeric based corrosion inhibitor, an oxidizer, a chelating inhibitor or combinations thereof;
a pH adjusting agent;
a solvent; and
a pH between about 1 and about 10;
forming a protective film on a polishing article coupled to the second electrode;
contacting the substrate to the polishing article;
providing relative motion between the substrate and the polishing article;
applying a bias between the first electrode and the second electrode; and
removing conductive material from the substrate surface.

11. The method of claim 10, further comprising forming a protective film on the second electrode.

12. The method of claim 10 wherein the applying the bias comprises applying a current density between about 3 mA/cm² and about 20 mA/cm² to the substrate.

13. The method of claim 10, wherein the acid based electrolyte comprises a phosphoric acid based electrolyte, a sulfuric acid based electrolyte, or combinations thereof.

14. The method of claim 10, wherein the amino acid based inhibitor comprises histidine, cysteine, cystine, or combinations thereof, the polymeric based corrosion inhibitor comprises polyethyleneimine glycol, polyacrylic acid, or combinations thereof, the oxidizer comprises iron nitrate, cesium nitrate, or combinations thereof, and the chelating inhibitor comprises ammonium citrate, ammonium hydroxide, citric acid, EDTA, polyphosphates, ethyleneiminediamine, ethyleneiminediamine tetra-acetic acid, or combinations thereof.

15. The method of claim 10, wherein the composition further comprises abrasive particles.

16. The method of claim 10, wherein the polishing composition has a conductivity in a range between about 20 mS/cm and about 80 mS/cm.

17. A composition for removing at least a conductive material from a substrate surface, comprising:
an acid based electrolyte;
a corrosion inhibitor selected from the group of an amino acid based inhibitor, a polymeric based corrosion inhibitor, an oxidizer, a chelating inhibitor or combinations thereof;
a pH adjusting agent;
a solvent; and
a pH between about 1 and about 10.

18. The composition of claim 17, wherein the acid based electrolyte comprises a phosphoric acid based electrolyte, a sulfuric acid based electrolyte, or a combinations thereof.

19. The composition of claim 17, wherein the amino acid based inhibitor comprises histidine, cysteine, cystine, or combinations thereof, the polymeric based corrosion inhibitor comprises polyethyleneimine glycol, polyacralic acid, or combinations thereof, the oxidizer comprises iron nitrate, cesium nitrate, or combinations thereof, and the chelating inhibitor comprises ammonium citrate, ammonium hydroxide, citric acid, EDTA, polyphosphates, ethyleneiminediamine, ethyleneiminediamine tetra-acetic acid, or combinations thereof.

20. The composition of claim 17, wherein the composition further comprises abrasive particles.
